(19) United States
(12) Patent Application Publication
(10) Pub. No.: US 2025/0063679 A1
(43) Pub. Date: Feb. 20, 2025

(54) TELECOMMUNICATIONS AND NETWORKING SHELF AND CIRCUIT CARD ASSEMBLIES

(71) Applicant: Ciena Corporation, Hanover, MD (US)

(72) Inventors: Simon Shearman, Carleton Place (CA); Peter Ajersch, Dunrobin (CA); Behazad Mohajer, Ottawa (CA); Daniel Rivaud, Ottawa (CA); Spencer Giacalone, Ottawa (CA); Fabien Colton, Kars (CA)

(21) Appl. No.: 18/233,929

(22) Filed: Aug. 15, 2023

(51) Int. Cl. H05K 7/14; H05K 7/18; H05K 7/20

(52) U.S. Cl. CPC H05K 7/1428; H05K 7/186; H05K 7/20254; H05K 7/20272

(57) ABSTRACT

A shelf system for use in a telecommunications or networking application, including a shelf assembly and a circuit card assembly conformally inserted into the shelf assembly. The circuit card assembly includes a printed circuit board assembly disposed in a case and a plurality of fabric ports coupled to the printed circuit board and accessible from a rear facing side of the case. The shelf assembly includes a housing defining an opening on a rear facing side of the housing adapted to provide access to the plurality of fabric ports from the rear facing side of the housing. The circuit card assembly further includes a plurality of client ports accessible from a front facing side of the case and the housing of the shelf assembly further defines an opening on a front facing side of the housing adapted to provide access to the plurality of client ports from the front facing side of the housing.

### TECHNICAL FIELD

The present disclosure relates generally to the telecommunications and networking fields. More particularly, the present disclosure relates to telecommunications and networking shelf and circuit card assemblies utilizing a generally octagonal arrangement of client ports and fabric ports around an application specific integrated circuit (ASIC) for reduced signal track length, lower power consumption, and improved cooling efficiency.

### BACKGROUND

In an optical switching system with cable based fabric, it is desirable to reduce signal track length between client ports and fabric ports and an ASIC in order to reduce power consumption. Such ports include quad small form factor pluggable-double density (QSFP-DD) ports and octal small form factor pluggable (OSFP) ports, for example.

Conventionally, most shelf and circuit card assemblies utilize generally forward facing higher power client ports and generally forward facing lower power fabric ports. The ASIC is disposed behind all these ports. This arrangement allows full frontal inlet airflow to pass over all optical and electrical ports to cooling fans located at the rear of the shelf and circuit card assemblies. Client ports may be spaced apart to accommodate larger heatsinks for the higher power devices as adequate faceplate space may be available. Fabric ports can be in ganged cages as they have lower power consumption and do not require larger heatsinks. Datacenter customers may use lower power client ports because they may be shorter reach (e.g., 2 km).

The present background is provided as illustrative environmental context only and should not be construed to be limiting in any manner. It will be readily apparent to those of ordinary skill in the art that the principles and concepts of the present disclosure may be implanted in other environmental contexts equally.

### BRIEF SUMMARY

The present disclosure is based on the concept that it is possible to reduce power consumption by arranging client ports closer to the designated client connections of the ASIC and fabric ports closer to the designated fabric connections of the ASIC. It is desirable to position the QSFP-DD/OSFP connectors within about 3 inches of these ASIC connections. Thus, the client ports are positioned on the front corners, and optionally along the front face, of a generally octagonal circuit card, with the fabric ports positioned on the rear corners. The side faces of the circuit card may be reserved for mounting guidance.

The ports or connections of the ASIC are arranged around the perimeter of the generally square ASIC body, with the client ports on the front side and half way back along adjacent sides of the ASIC body, for example. On the same chip, the fabric ports may be arranged around the opposite back corners. To reduce track length as much as possible, the QSFP-DD/OSFP connectors that interact with the ASIC are disposed at substantially 45-degree angles to the ASIC on all four corners. If the ASIC body represents four sides of the square, then the QSFP-DD/connectors are arranged at 45 degrees to the square, forming a generally octagonal circuit card arrangement. The ASIC may also be rotated 45 degrees such that the sides of the ASIC body are parallel to the port surfaces, with the appropriate connections being disposed in closest proximity on the ASIC.

In this generally octagonal arrangement, the client ports are arranged towards the front outer corners of the equipment frame, while the rear outer corners of the equipment frame are used for fabric switching. The side faces of the circuit card assembly are reserved for mounting guidance when the circuit card assembly is inserted into the shelf assembly. An extended rear portion of the circuit card assembly disposed between the back corner fabric ports provides area for power entry and handling, control, and liquid cooling ingress and egress, when used. In general, the shelf and circuit card assemblies of the present disclosure may utilize air cooling and/or liquid cooling, such as in a hybrid cooling system.

As contemplated herein, by way of example only, there are two types of circuit card assemblies that may be used in the shelf assembly, providing a switching fabric topology. A circuit card assembly with client ports to be switched may be referred to as a “Client box,” which may also include fabric ports to exchange data with a second type of fabric box circuit card assembly referred to as a “Fabric box.” Thus, the present disclosure contemplates multiple similar arrangements of client ports and fabric ports on circuit card assemblies that plug into a unique generally octagonal shaped shelf assembly, providing four sides of port access with minimized signal track length, reduced power consumption, and improved cooling efficiency.

In one illustrative embodiment, the present disclosure provides a circuit card assembly adapted to be inserted into a conformal shelf assembly, the circuit card assembly including a printed circuit board assembly disposed in a case and a plurality of fabric ports coupled to the printed circuit board and accessible from a rear facing side of the case. In a Client box, the circuit card assembly further includes a plurality of client ports coupled to the printed circuit board and accessible from a front facing side of the case. In this embodiment, the case includes a generally octagonal shaped portion, the plurality of fabric ports are accessible from a rear and side facing corner of the case, and the plurality of client ports are accessible from a front and side facing corner of the case. The circuit card assembly further includes an application specific integrated circuit coupled to the printed circuit board and disposed between the plurality of fabric ports and the plurality of client ports in a central portion of the printed circuit board. Optionally, the case further includes a generally rectangular or other shaped portion coupled to the generally octagonal shaped portion at a back portion of the case. The generally rectangular or other shaped portion includes one or more of: a busbar; a controller; a plurality of guide pins; and a plurality of cooling liquid quick disconnects. Optionally, the circuit card assembly further includes a liquid cooling plate disposed within the case adjacent to a component side of the printed circuit board. The circuit card assembly further includes guide rails coupled to sides of the case.

In another illustrative embodiment, the present disclosure provides a shelf assembly adapted to receive an inserted conformal circuit card assembly, the shelf assembly including a housing defining an opening on a rear facing side of the housing adapted to provide access to a plurality of fabric ports of the circuit card assembly from the rear facing side of the housing. In a Client box, the housing further defines an opening on a front facing side of the housing adapted to provide access to a plurality of client ports of the circuit card assembly from the front facing side of the housing. In this embodiment, the housing includes a generally octagonal shaped portion, the plurality of fabric ports are accessible from a rear and side facing corner of the housing, and the plurality of client ports are accessible from a front and side facing corner of the housing. The circuit card assembly includes an application specific integrated circuit coupled to a printed circuit board with the plurality of fabric ports and the plurality of client ports and disposed between the plurality of fabric ports and the plurality of client ports in a central portion of the printed circuit board. Optionally, the housing further includes a generally rectangular or other shaped portion coupled to the generally octagonal shaped portion at a back portion of the housing. The generally rectangular or other shaped portion includes one or more of: a backplane; a plurality of guide pins; and a plurality of cooling liquid quick disconnects. The shelf assembly further includes one or more of: a vertical air plenum disposed at a back of the housing; a vertical air plenum disposed at a side of the housing; a vertical liquid manifold disposed at the back of the housing; one or more fan assemblies disposed at the back of the housing; one or more fan assemblies disposed at the side of the housing; and one or more fan assemblies disposed at a top of the housing. Sides of the housing define internal guide slots adapted to receive guide rails coupled to sides of a case of the circuit card assembly.

In a further illustrative embodiment, the present disclosure provides a shelf system for use in a telecommunications or networking application, the shelf system including a shelf assembly and a circuit card assembly conformally inserted into the shelf assembly. The circuit card assembly includes a printed circuit board assembly disposed in a case and a plurality of fabric ports coupled to the printed circuit board and accessible from a rear facing side of the case. The shelf assembly includes a housing defining an opening on a rear facing side of the housing adapted to provide access to the plurality of fabric ports of the circuit card assembly from the rear facing side of the housing. In a Client box, the circuit card assembly further includes a plurality of client ports coupled to the printed circuit board and accessible from a front facing side of the case and the housing of the shelf assembly further defines an opening on a front facing side of the housing adapted to provide access to the plurality of client ports of the circuit card assembly from the front facing side of the housing. In this embodiment, the case and the housing each include a generally octagonal shaped portion, the plurality of fabric ports are accessible from a rear and side facing corner of the case and housing, and the plurality of client ports are accessible from a front and side facing corner of the case and housing. The circuit card assembly further includes an application specific integrated circuit coupled to the printed circuit board and disposed between the plurality of fabric ports and the plurality of client ports in a central portion of the printed circuit board.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 illustrates a conventional shelf assembly and circuit card assembly;

FIG. 2A illustrates one client box embodiment of the shelf assembly and circuit card assembly of the present disclosure;

FIG. 2B illustrates one fabric box embodiment of the shelf assembly and circuit card assembly of the present disclosure;

FIG. 3A illustrates another client box embodiment of the shelf assembly and circuit card assembly of the present disclosure;

FIG. 3B illustrates another fabric box embodiment of the shelf assembly and circuit card assembly of the present disclosure;

FIG. 4A illustrates a further client box embodiment of the shelf assembly and circuit card assembly of the present disclosure;

FIG. 4B illustrates a further fabric box embodiment of the shelf assembly and circuit card assembly of the present disclosure;

FIG. 5 illustrates a still further embodiment of the shelf assembly and circuit card assembly of the present disclosure;

FIG. 6 illustrates a still further embodiment of the shelf assembly and circuit card assembly of the present disclosure;

FIG. 7A illustrates possible cooling airflow configurations utilized with the client box of the shelf assembly and circuit card assembly of the present disclosure;

FIG. 7B illustrates possible cooling airflow configurations utilized with the fabric box of the shelf assembly and circuit card assembly of the present disclosure;

FIG. 8 illustrates cooling ducts utilized with the shelf assembly and circuit card assembly of the present disclosure;

FIG. 9A illustrates another possible cooling airflow configuration utilized with the shelf assembly and circuit card assembly of the present disclosure;

FIG. 9B illustrates a further possible cooling airflow configuration utilized with the shelf assembly and circuit card assembly of the present disclosure;

FIG. 10 illustrates the front of one embodiment of the shelf assembly of the present disclosure with a plurality of circuit cards assemblies (Client boxes and Fabric boxes) installed;

FIG. 11 illustrates the back of one embodiment of the shelf assembly of the present disclosure with a plurality of circuit cards assemblies (Client boxes and Fabric boxes) installed;

FIG. 12 illustrates one embodiment of the circuit card assembly of the present disclosure;

FIG. 13 illustrates a still further embodiment of the shelf assembly and circuit card assembly of the present disclosure;

FIG. 14A illustrates an embodiment of the shelf assembly of the present disclosure;

FIG. 14B illustrates another embodiments of the shelf assembly of the present disclosure;

FIG. 15A illustrates another embodiment of the shelf assembly of the present disclosure;

FIG. 15B illustrates the embodiment of the shelf assembly of the present disclosure with a removable guide track;

FIG. 16 illustrates a further embodiment of the shelf assembly of the present disclosure;

FIG. 17 illustrates one embodiment of a liquid cooling system for the circuit card assemblies of the present disclosure;

FIG. 18 illustrates a still further embodiment of the shelf assembly and circuit card assembly of the present disclosure;

FIG. 19 illustrates a still further embodiment of the shelf assembly and circuit card assembly of the present disclosure;

FIG. 20A illustrates a still further client box embodiment of the shelf assembly and circuit card assembly of the present disclosure;

20B illustrates a still further fabric box embodiment of the shelf assembly and circuit card assembly of the present disclosure; and

FIG. 21 illustrates a still further embodiment of the shelf assembly and circuit card assembly of the present disclosure.

It will be readily apparent to those of ordinary skill in the art that aspects and features of each of the illustrated embodiments may be incorporated, omitted, and/or combined as desired in a given application, without limitation.

### DETAILED DESCRIPTION

Again, the present disclosure is based on the concept that it is possible to reduce power consumption by arranging client ports closer to the designated client connections of the ASIC and fabric ports closer to the designated fabric connections of the ASIC. It is desirable to position the QSFP-DD/OSFP connectors within about 3 inches of these ASIC connections. Thus, the client ports are positioned on the front corners, and optionally along the front face, of a generally octagonal circuit card, with the fabric ports positioned on the rear corners. The side faces of the circuit card may be reserved for mounting guidance.

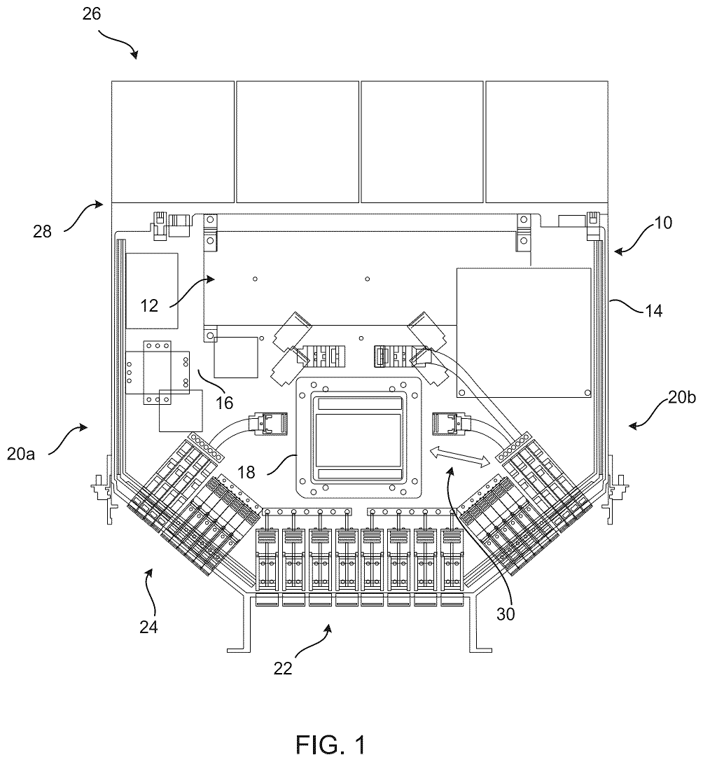

FIG. 1 illustrates a conventional shelf assembly 10 and circuit card assembly 12, collectively referred to as a “shelf system.” Here, the shelf assembly 10 includes a chassis or housing 14 that is adapted to receive multiple inserted circuit card assemblies 12 in a vertical configuration. Each circuit card assembly 12 includes a board 16 (i.e., a printed circuit board assembly (PCBA)) that includes an ASIC 18 and multiple additional components that are not described in further detail here. As illustrated, the side edges 20a and 20b of the board 16 or a surrounding frame may be used as a mounting guide for inserting the circuit card assembly 12 into the shelf assembly 10, which may include a plurality of corresponding guide rails. The circuit card assembly 12 also includes a plurality of ports provided on the board 16, including a plurality of client ports 22 and a plurality of fabric ports 24 configured to receive a plurality of QSFP-DD/OSFP connectors or the like. These ports may include individual cages and connectors, or ganged cages and connectors. As illustrated, in this shelf assembly 10, the client ports 22 are disposed at the front face of the circuit card assembly 12, while the fabric ports 24 are disposed at the front angled corners of the circuit card assembly 12 on either side of the client ports 22. The ASIC 18 is disposed on the board 16 behind the client ports 22 and the fabric ports 24. Although other precise configurations are possible, a common thread is that both the client ports 22 and the fabric ports 24 are accessible from the front of the shelf assembly 10 and circuit card 12. As also illustrated, air cooling is provided to the board components and connections via one or more fans 26 disposed at the back or the shelf assembly 10, near the backplane 28. The fans 26 are typically configured to generate front-to-back airflow. Other flow paths are possible by different placement and/or orientation of the fans 26.

In this circuit card assembly 12, the ports or connections of the ASIC 18 are generally arranged around the perimeter of the generally square ASIC body, with the client ports on the front side and half way back along adjacent sides of the ASIC body, for example. On the same chip, the fabric ports may be arranged around the opposite back corners. The track lengths from the client ports 22 to the client ports of the ASIC 18 are thus relatively short, given the placement of the ASIC 18 behind the client ports 22, but the track lengths from the fabric ports 24 to the fabric ports of the ASIC 18 are relatively long, given the placement of the ASIC 18 behind the fabric ports 24. This variable track length 30, which may be advantageously short or disadvantageously long, is illustrated in FIG. 1.

Per the present disclosure, the ports or connections of the ASIC may also be arranged around the perimeter of the generally square ASIC body, with the client ports on the front side and half way back along adjacent sides of the ASIC body, for example. On the same chip, the fabric ports may be arranged around the opposite back corners. To reduce track length as much as possible, the QSFP-DD/OSFP connectors that interact with the ASIC are disposed at substantially 45-degree angles to the ASIC on all four corners. If the ASIC body represents four sides of the square, then the QSFP-DD/connectors are arranged at 45 degrees to the square, forming a generally octagonal circuit card arrangement. The ASIC may also be rotated 45 degrees such that the sides of the ASIC body are parallel to the port surfaces, with the appropriate connections being disposed in closest proximity on the ASIC.

In this generally octagonal arrangement, the client ports are arranged towards the front outer corners of the equipment frame, while the rear outer corners of the equipment frame are used for fabric switching. The side faces of the circuit card assembly are reserved for mounting guidance when the circuit card assembly is inserted into the shelf assembly. An extended rear portion of the circuit card assembly disposed between the back corner fabric ports provides area for power entry and handling, control, and liquid cooling ingress and egress, when used. In general, the shelf and circuit card assemblies of the present disclosure may utilize air cooling and/or liquid cooling, such as in a hybrid cooling system.

Again, as contemplated herein, by way of example only, there are two types of circuit card assemblies that may be used in the shelf assembly, providing a switching fabric topology. A circuit card assembly with client ports to be switched may be referred to as a Client box, which may also include fabric ports to exchange data with a second type of fabric box circuit card assembly referred to as a Fabric box. Thus, the present disclosure contemplates multiple similar arrangements of client ports and fabric ports on circuit card assemblies that plug into a unique generally octagonal shaped shelf assembly, providing four sides of port access with minimized signal track length, reduced power consumption, and improved cooling efficiency.

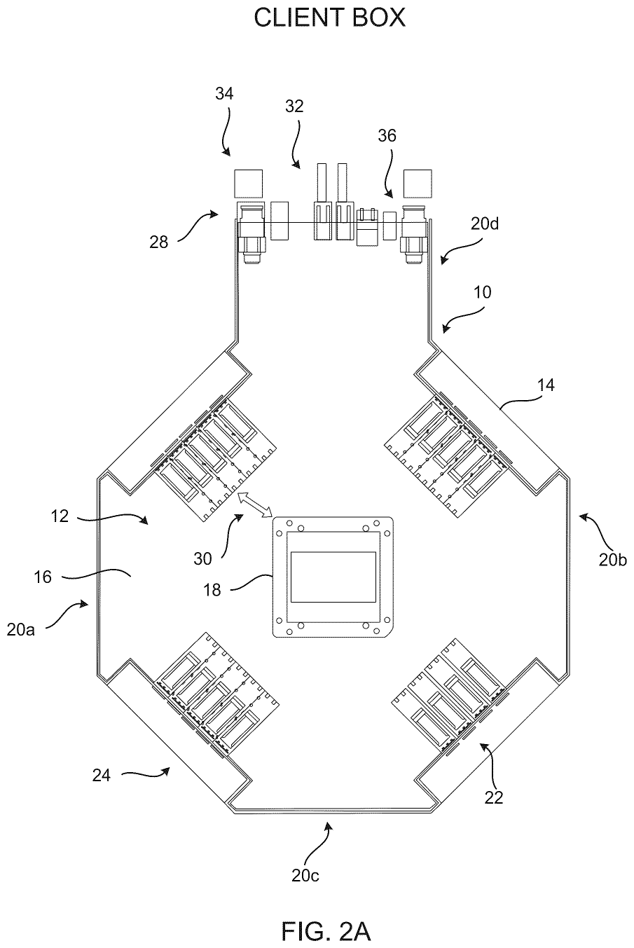

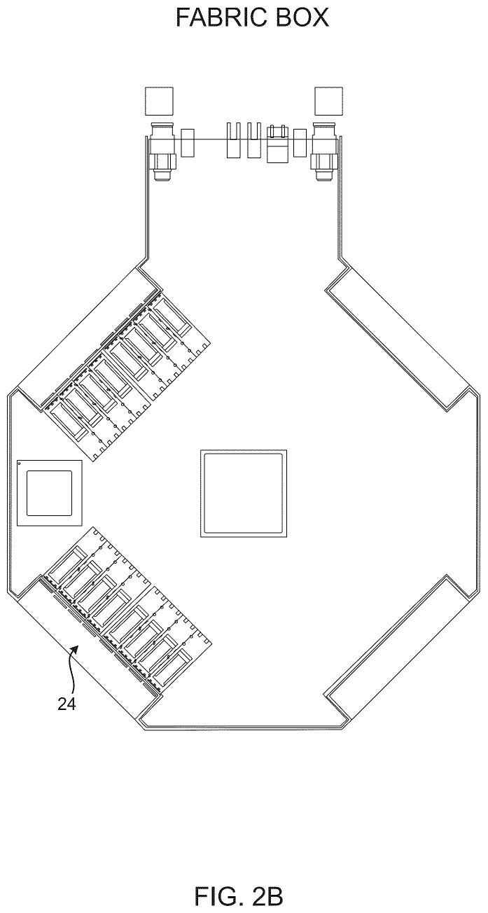

FIG. 2 illustrate one client box embodiment (FIG. 2A) and one fabric box embodiment (FIG. 2B) of the shelf assembly 10 and circuit card assembly 12 of the present disclosure. Again, the shelf assembly 10 includes a chassis or housing 14 that is adapted to receive multiple inserted circuit card assemblies 12 in a vertical configuration. Each circuit card assembly 12 includes a board 16 (i.e., a PCBA) that includes an ASIC 18 and multiple additional components that are not described in further detail here. As illustrated, the side edges 20a and 20b of the board 16 or a surrounding frame may be used as a mounting guide for inserting the circuit card assembly 12 into the shelf assembly 10, which may include a plurality of corresponding guide rails.

The circuit card assembly 12 also includes a plurality of ports provided on the board 16, including a plurality of client ports 22 and a plurality of fabric ports 24 configured to receive a plurality of QSFP-DD/OSFP connectors or the like. These ports may include individual cages and connectors, or ganged cages and connectors. As illustrated, in this shelf assembly 10, the client ports 22 (also referred to as line ports) of the Client box are disposed at the front and rear corner faces on one side of the circuit card assembly 12 (the right side is illustrated, but this could alternatively be the left side). The fabric ports 24 are disposed at the front and rear corner faces on the opposite side of the circuit card assembly 12 (the left side is illustrated, but this could alternatively be the right side). These corner faces are roughly 45-degree angled faces disposed between the side edges 20a and 20b and a front edge 20c and rear portion 20d of the board 16. Thus, the side edges 20a and 20b, front edge 20c, and rear portion 20d of the board 16 form a generally octagonal planar structure, with the rear portion 20d being a generally rectangular protrusion of the board 16. The ASIC 18 is disposed on the board 16 substantially centered between the client ports 22 and the fabric ports 24. As illustrated, in this shelf assembly 10, the fabric ports 24 of the Fabric box are disposed at the front and rear corner faces on one side of the circuit card assembly 12 (the left side is illustrated, but this could also be the right side). Again, these corner faces are roughly 45-degree angled faces disposed between the side edges 20a and 20b and a front edge 20c and rear portion 20d of the board 16. Thus, the side edges 20a and 20b, front edge 20c, and rear portion 20d of the board 16 form a generally octagonal planar structure, with the rear portion 20d being a generally rectangular protrusion of the board 16.

Here, the client ports 22 are accessible from the right side of the shelf assembly 10 and Client box circuit card 12 and the fabric ports 24 are accessible from the left side of the shelf assembly 10 and both Client box and Fabric box circuit cards 12. Air cooling may be provided to the board components and connections, with front-to-back, side-to-back, and/or side-to-side airflow. Liquid cooling may also or alternatively be provided to the board components and connections.

In this circuit card assembly 12, the ports or connections of the ASIC 18 are generally arranged around the perimeter of the generally square ASIC body, with the client ports on the right half of the ASIC body. On the same chip, the fabric ports may be arranged around the left half of the ASIC body. The track lengths from the client ports 22 to the client ports of the ASIC 18 are thus relatively short, given the placement of the ASIC 18 adjacent to the client ports 22. The track lengths from the fabric ports 24 to the fabric ports of the ASIC 18 are also relatively short, given the placement of the ASIC 18 adjacent to the fabric ports 24. This track length 30, which is advantageously short, is illustrated in FIG. 2A.

Per the present disclosure, the QSFP-DD/OSFP connectors that interact with the ASIC 18 are disposed at substantially 45-degree angles to the ASIC 18 on all four corners. If the ASIC body represents four sides of the square, then the QSFP-DD/connectors are arranged at 45 degrees to the square, forming a generally octagonal circuit card arrangement. The ASIC 18 may also be rotated 45 degrees such that the sides of the ASIC body are parallel to the port surfaces, with the appropriate connections being disposed in closest proximity on the ASIC 18.

In this generally octagonal arrangement, the client ports 22 are arranged towards the right outer corners of the equipment frame, while the left outer corners of the equipment frame are used for fabric switching. The side faces 20a and 20b of the circuit card assembly 12 are reserved for mounting guidance when the circuit card assembly 12 is inserted into the shelf assembly 10. An extended rear portion 20d of the circuit card assembly 12 disposed between the back corners provides area for power entry and handling, control, and liquid cooling ingress and egress, when used. In general, the shelf and circuit card assemblies 10 and 12 of the present disclosure may utilize air cooling and/or liquid cooling, such as in a hybrid cooling system.

The backplane 28 of the shelf assembly 10 includes busbars 32 for making power connections between the circuit card assemblies 12, vertical manifolds 34 for liquid distribution, and liquid quick disconnects 36 for liquid cooling.

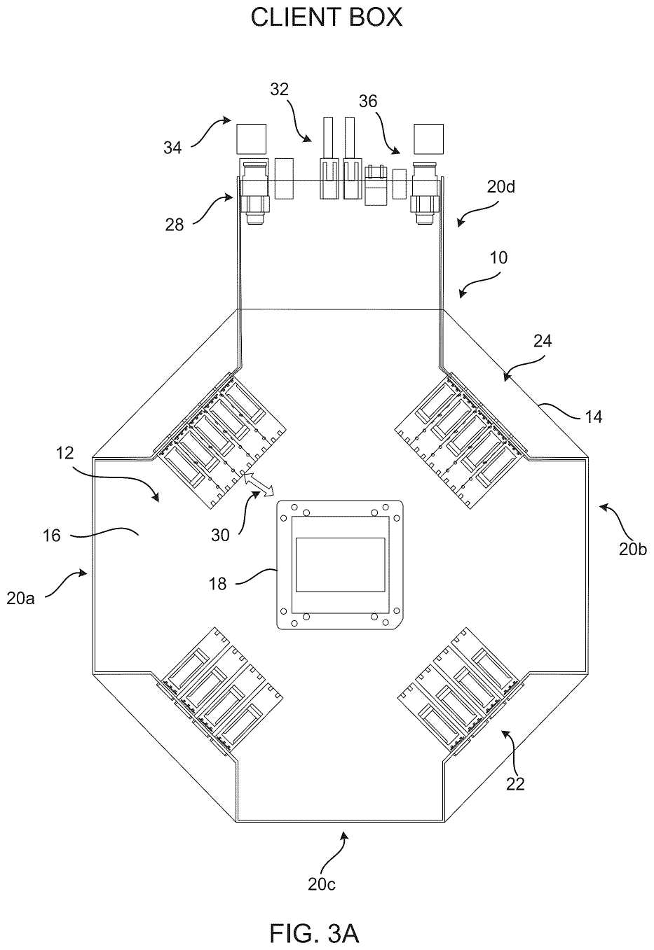

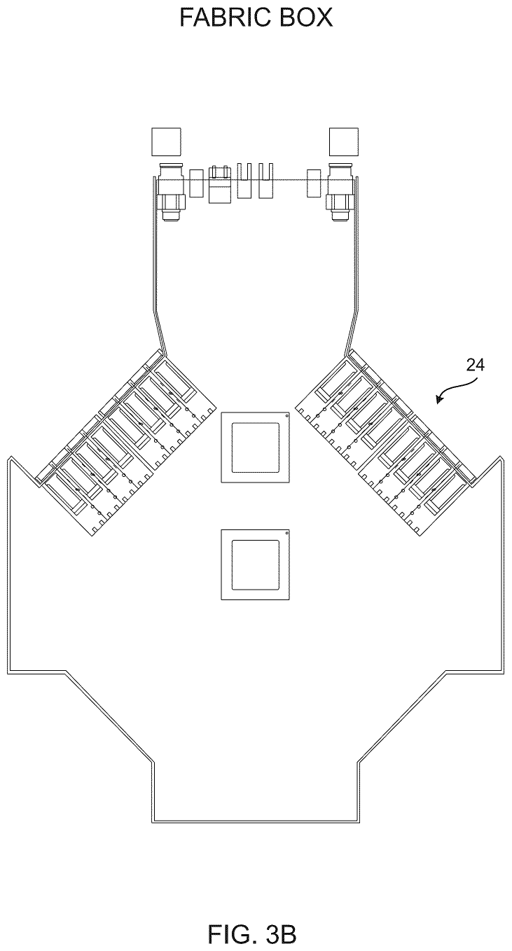

FIG. 3 illustrate another client box embodiment (FIG. 3A) and another fabric box embodiment (FIG. 3B) of the shelf assembly 10 and circuit card assembly 12 of the present disclosure. Again, the shelf assembly 10 includes a chassis or housing 14 that is adapted to receive multiple inserted circuit card assemblies 12 in a vertical configuration. Each circuit card assembly 12 includes a board 16 (i.e., a PCBA) that includes an ASIC 18 and multiple additional components that are not described in further detail here. As illustrated, the side edges 20a and 20b of the board 16 or a surrounding frame may be used as a mounting guide for inserting the circuit card assembly 12 into the shelf assembly 10, which may include a plurality of corresponding guide rails.

The circuit card assembly 12 also includes a plurality of ports provided on the board 16, including a plurality of client ports 22 and a plurality of fabric ports 24 configured to receive a plurality of QSFP-DD/OSFP connectors or the like. These ports may include individual cages and connectors, or ganged cages and connectors. As illustrated, in this shelf assembly 10, the client ports 22 (also referred to as line ports) of the Client box are disposed at the front corner faces of the circuit card assembly 12. The fabric ports 24 are disposed at the rear corner faces of the circuit card assembly 12. These corner faces are roughly 45-degree angled faces disposed between the side edges 20a and 20b and a front edge 20c and rear portion 20d of the board 16. Thus, the side edges 20a and 20b, front edge 20c, and rear portion 20d of the board 16 form a generally octagonal planar structure, with the rear portion 20d being a generally rectangular protrusion of the board 16. The ASIC 18 is disposed on the board 16 substantially centered between the client ports 22 and the fabric ports 24. As illustrated, in this shelf assembly 10, the fabric ports 24 of the Fabric box are disposed at the rear corner faces of the circuit card assembly 12. Again, these corner faces are roughly 45-degree angled faces disposed between the side edges 20a and 20b and a front edge 20c and rear portion 20d of the board 16. Thus, the side edges 20a and 20b, front edge 20c, and rear portion 20d of the board 16 form a generally octagonal planar structure, with the rear portion 20d being a generally rectangular protrusion of the board 16.

Here, the client ports 22 are accessible from the front side of the shelf assembly 10 and Client box circuit card 12 and the fabric ports 24 are accessible from the rear side of the shelf assembly 10 and both Client box and Fabric box circuit cards 12. Air cooling may be provided to the board components and connections, with front-to-back, side-to-back, and/or side-to-side airflow. Liquid cooling may also or alternatively be provided to the board components and connections.

In this circuit card assembly 12, the ports or connections of the ASIC 18 are generally arranged around the perimeter of the generally square ASIC body, with the client ports on the front half of the ASIC body. On the same chip, the fabric ports may be arranged around the rear half of the ASIC body. The track lengths from the client ports 22 to the client ports of the ASIC 18 are thus relatively short, given the placement of the ASIC 18 adjacent to the client ports 22. The track lengths from the fabric ports 24 to the fabric ports of the ASIC 18 are also relatively short, given the placement of the ASIC 18 adjacent to the fabric ports 24. This track length 30, which is advantageously short, is illustrated in FIG. 3.

Per the present disclosure, the QSFP-DD/OSFP connectors that interact with the ASIC 18 are disposed at substantially 45-degree angles to the ASIC 18 on all four corners. If the ASIC body represents four sides of the square, then the QSFP-DD/connectors are arranged at 45 degrees to the square, forming a generally octagonal circuit card arrangement. The ASIC 18 may also be rotated 45 degrees such that the sides of the ASIC body are parallel to the port surfaces, with the appropriate connections being disposed in closest proximity on the ASIC 18.

In this generally octagonal arrangement, the client ports 22 are arranged towards the front outer corners of the equipment frame, while the rear outer corners of the equipment frame are used for fabric switching. The side faces 20a and 20b of the circuit card assembly 12 are reserved for mounting guidance when the circuit card assembly 12 is inserted into the shelf assembly 10. An extended rear portion 20d of the circuit card assembly 12 disposed between the back corners provides area for power entry and handling, control, and liquid cooling ingress and egress, when used. In general, the shelf and circuit card assemblies 10 and 12 of the present disclosure may utilize air cooling and/or liquid cooling, such as in a hybrid cooling system.

The backplane 28 of the shelf assembly 10 includes busbars 32 for making power connections between the circuit card assemblies 12, vertical manifolds 34 for liquid distribution, and liquid quick disconnects 36 for liquid cooling.

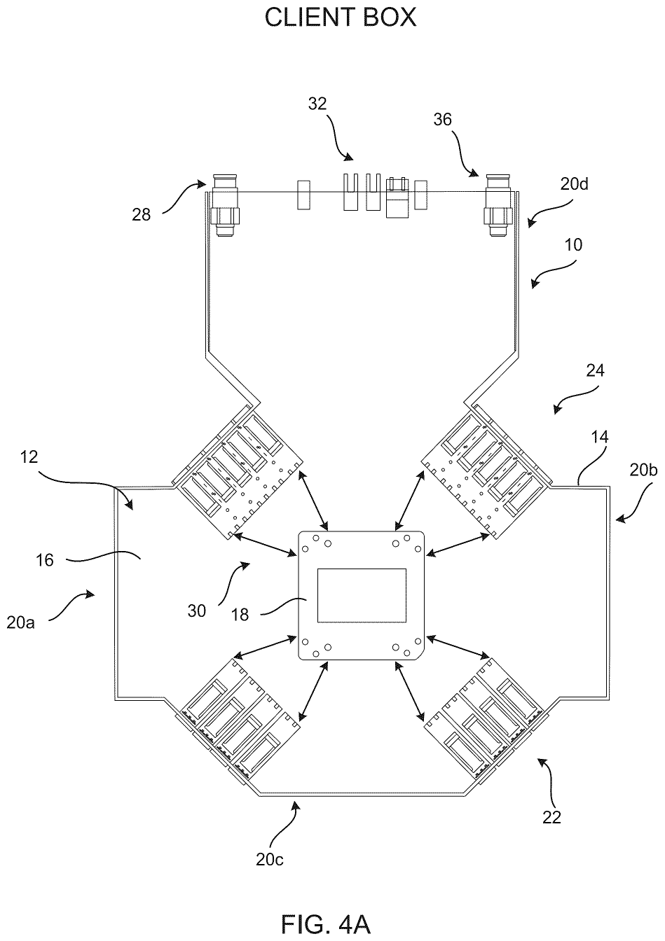

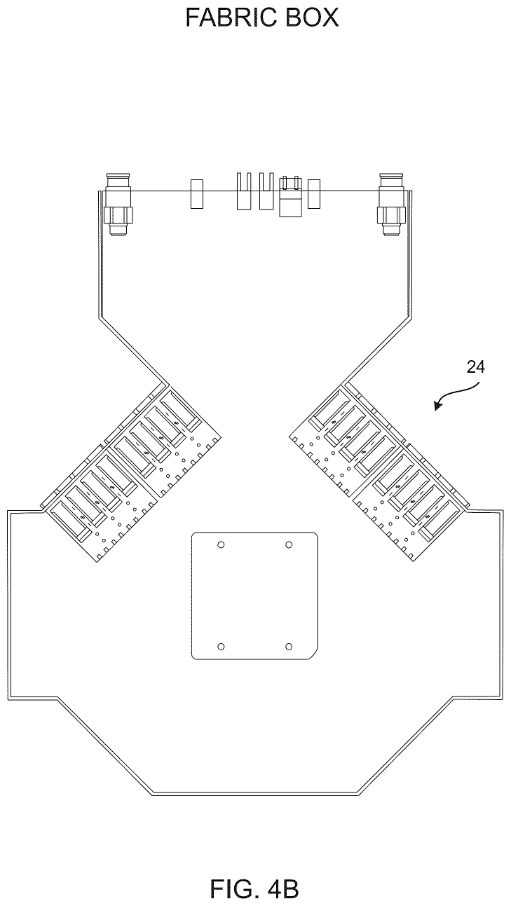

FIG. 4 illustrate a further client box embodiment (FIG. 4A) and a further fabric box embodiments (FIG. 4B) of the shelf assembly 10 and circuit card assembly 12 of the present disclosure. Again, the shelf assembly 10 includes a chassis or housing 14 that is adapted to receive multiple inserted circuit card assemblies 12 in a vertical configuration. Each circuit card assembly 12 includes a board 16 (i.e., a PCBA) that includes an ASIC 18 and multiple additional components that are not described in further detail here. As illustrated, the side edges 20a and 20b of the board 16 or a surrounding frame may be used as a mounting guide for inserting the circuit card assembly 12 into the shelf assembly 10, which may include a plurality of corresponding guide rails.

The circuit card assembly 12 also includes a plurality of ports provided on the board 16, including a plurality of client ports 22 and a plurality of fabric ports 24 configured to receive a plurality of QSFP-DD/OSFP connectors or the like. These ports may include individual cages and connectors, or ganged cages and connectors. As illustrated, in this shelf assembly 10, the client ports 22 (also referred to as line ports) of the Client box are disposed at the front corner faces of the circuit card assembly 12. The fabric ports 24 are disposed at the rear corner faces of the circuit card assembly 12. These corner faces are roughly 45-degree angled faces disposed between the side edges 20a and 20b and a front edge 20c and rear portion 20d of the board 16. Thus, the side edges 20a and 20b, front edge 20c, and rear portion 20d of the board 16 form a generally octagonal planar structure, with the rear portion 20d being a generally tail shaped protrusion of the board 16. The ASIC 18 is disposed on the board 16 substantially centered between the client ports 22 and the fabric ports 24. As illustrated, in this shelf assembly 10, the fabric ports 24 of the Fabric box are disposed at the rear corner faces of the circuit card assembly 12. Again, these corner faces are roughly 45-degree angled faces disposed between the side edges 20a and 20b and a front edge 20c and rear portion 20d of the board 16. Thus, the side edges 20a and 20b, front edge 20c, and rear portion 20d of the board 16 form a generally octagonal planar structure, with the rear portion 20d being a generally tail shaped protrusion of the board 16.

Here, the client ports 22 are accessible from the front side of the shelf assembly 10 and Client box circuit card 12 and the fabric ports 24 are accessible from the rear side of the shelf assembly 10 and both Client box and Fabric box circuit cards 12. Air cooling may be provided to the board components and connections, with front-to-back, side-to-back, and/or side-to-side airflow. Liquid cooling may also or alternatively be provided to the board components and connections.

In this circuit card assembly 12, the ports or connections of the ASIC 18 are generally arranged around the perimeter of the generally square ASIC body, with the client ports on the front half of the ASIC body. On the same chip, the fabric ports may be arranged around the rear half of the ASIC body. The track lengths from the client ports 22 to the client ports of the ASIC 18 are thus relatively short, given the placement of the ASIC 18 adjacent to the client ports 22. The track lengths from the fabric ports 24 to the fabric ports of the ASIC 18 are also relatively short, given the placement of the ASIC 18 adjacent to the fabric ports 24. This track length 30, which is advantageously short, is illustrated in FIG. 4A.

Per the present disclosure, the QSFP-DD/OSFP connectors that interact with the ASIC 18 are disposed at substantially 45-degree angles to the ASIC 18 on all four corners. If the ASIC body represents four sides of the square, then the QSFP-DD/connectors are arranged at 45 degrees to the square, forming a generally octagonal circuit card arrangement. The ASIC 18 may also be rotated 45 degrees such that the sides of the ASIC body are parallel to the port surfaces, with the appropriate connections being disposed in closest proximity on the ASIC 18.

In this generally octagonal arrangement, the client ports 22 are arranged towards the front outer corners of the equipment frame, while the rear outer corners of the equipment frame are used for fabric switching. The side faces 20a and 20b of the circuit card assembly 12 are reserved for mounting guidance when the circuit card assembly 12 is inserted into the shelf assembly 10. An extended rear portion 20d of the circuit card assembly 12 disposed between the back corners provides area for power entry and handling, control, and liquid cooling ingress and egress, when used. In general, the shelf and circuit card assemblies 10 and 12 of the present disclosure may utilize air cooling and/or liquid cooling, such as in a hybrid cooling system.

Here, the backplane 28 of the shelf assembly 10 includes busbars 32 for making power connections between the circuit card assemblies 12 and liquid quick disconnects 36 for liquid cooling.

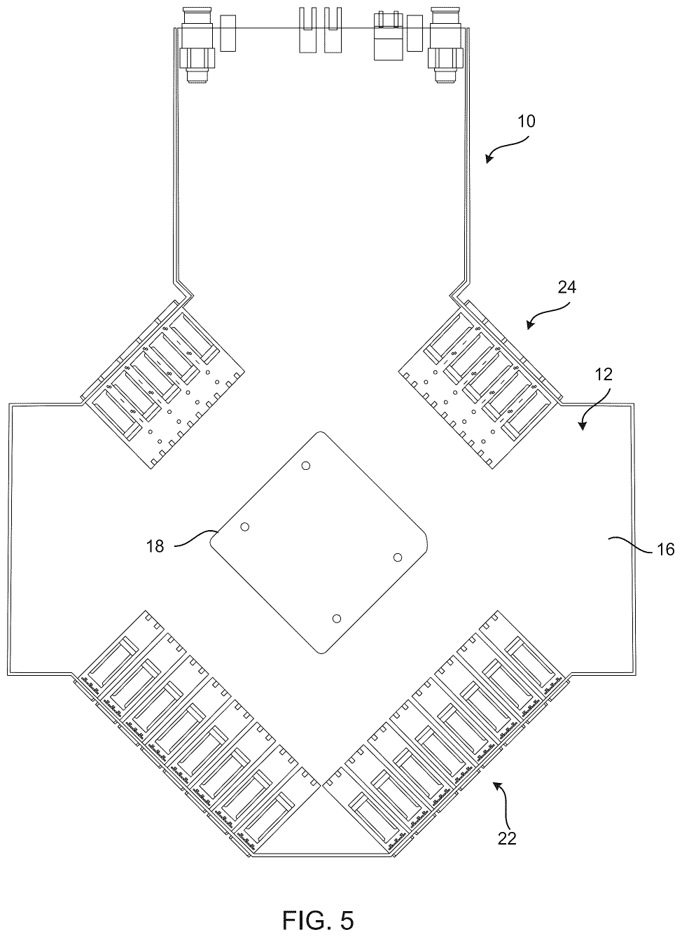

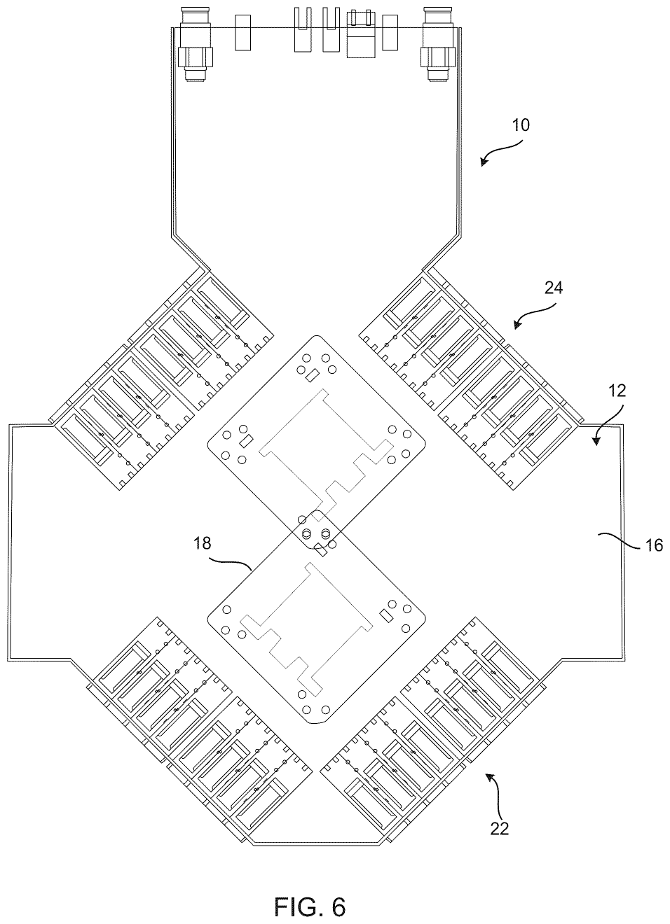

FIGS. 5 and 6 illustrate still further embodiments of the shelf assembly 10 and circuit card assembly 12 of the present disclosure. Referring to FIG. 5, the ASIC 18 is placed on a diagonal in the middle of the generally octagonal portion of the board 16 such that the flat sides of the ASIC body with the client connections and fabric connections are disposed substantially parallel to the respective client ports 22 and fabric ports 24. This arrangement minimizes overall track length. Referring to FIG. 6, dual ASICs 18 are each placed on a diagonal in the middle of the generally octagonal portion of the board 16 such that the flat sides of the ASIC bodies with the client connections and fabric connections are disposed substantially parallel to the respective client ports 22 and fabric ports 24. This arrangement further minimizes overall track length.

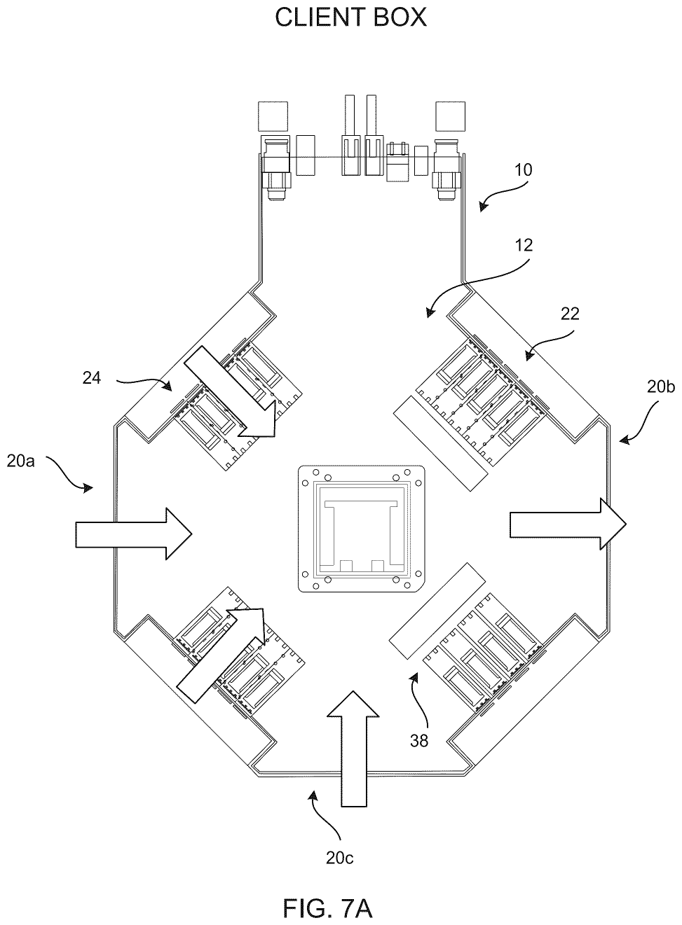

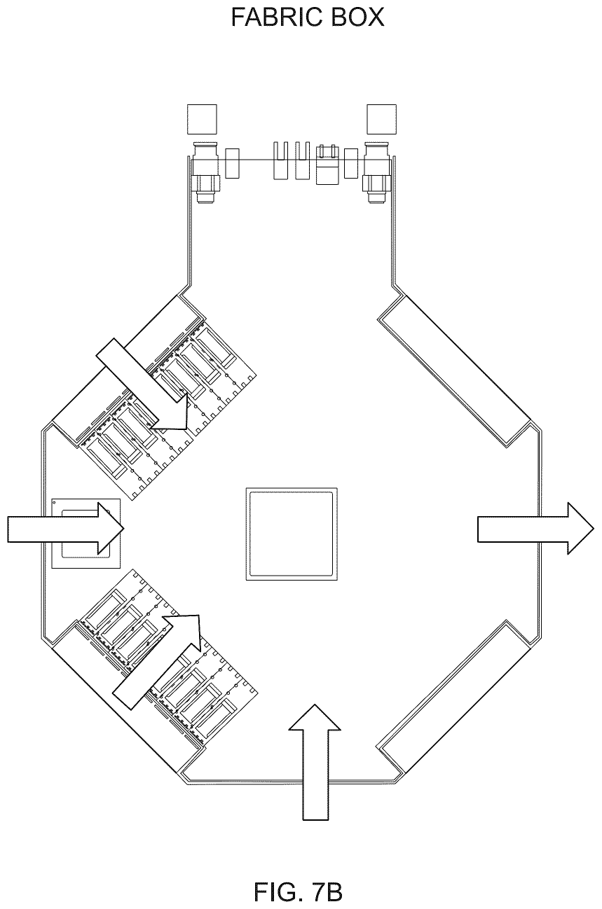

FIG. 7 illustrate possible cooling airflow configurations utilized with the client box (FIG. 7A) and the fabric box (FIG. 7B) the shelf assembly 10 and circuit card assembly 12 of the present disclosure. As is shown, the airflow is drawn in through the front face 20c and the left side face 20a of the chassis assembly 10 and each circuit card assembly 12, as well as through the associated fabric ports 24. Optionally, the corresponding line ports 22 may be cooled by cold plates which are themselves liquid cooled via coolant distribution through a manifold 38.

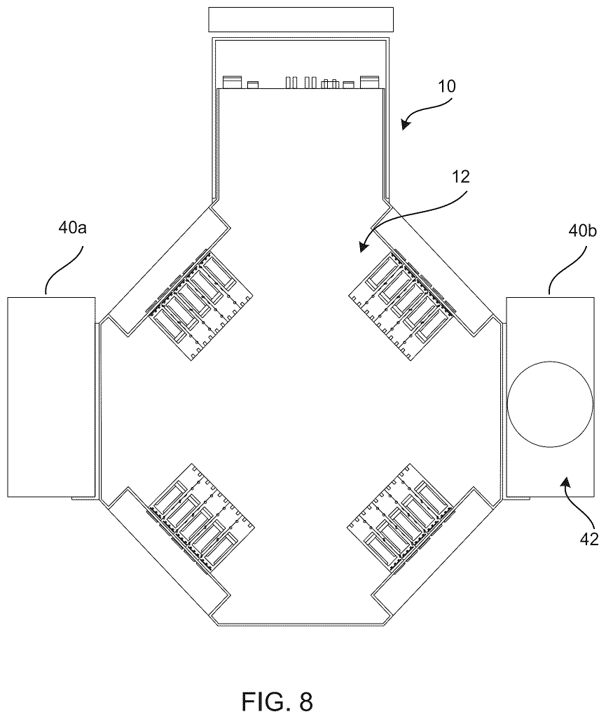

FIG. 8 illustrates cooling ducts 40a and 40b utilized with the shelf assembly 10 and circuit card assembly 12 of the present disclosure. A fan assembly 42 is mounted on the top of one of the ducts 40b and draws a cooling airflow from the other duct 40a across the heated components disposed in between. The ducts 40a and 40b acted as vertical conduits or plenums for the airflow at the side of the shelf assembly 10.

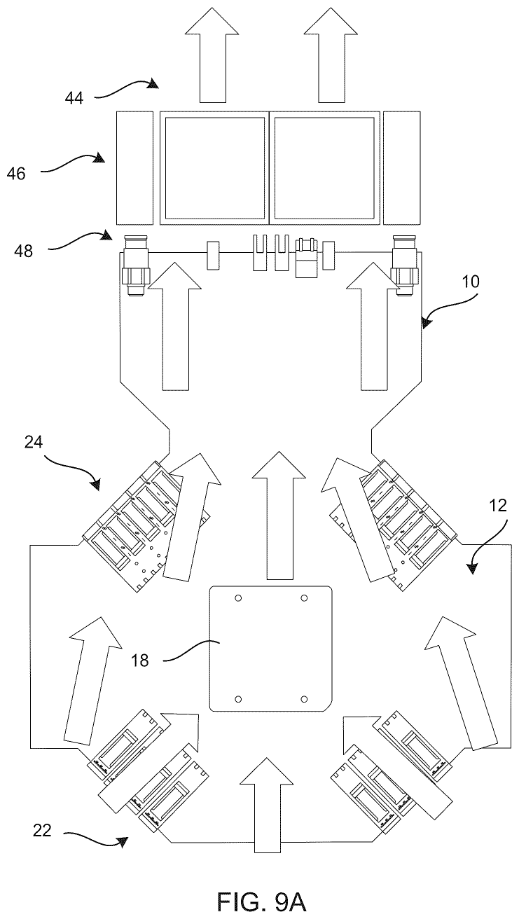

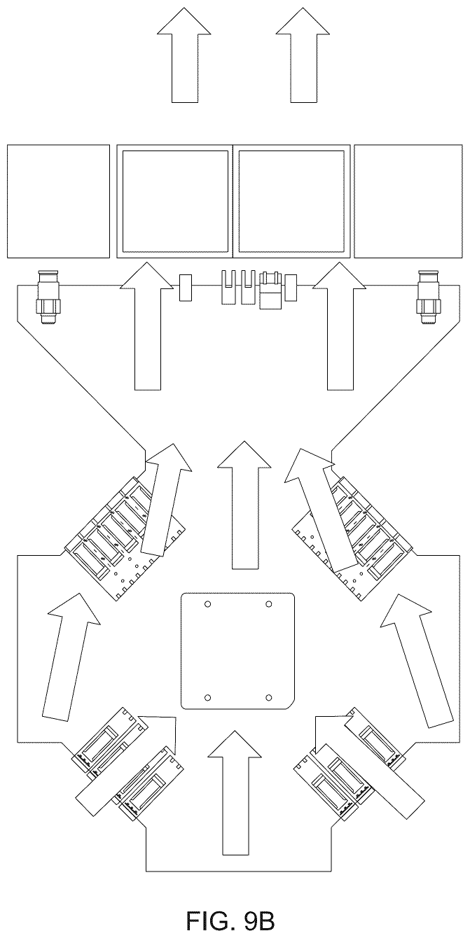

FIG. 9A illustrate another possible cooling airflow configuration utilized with the shelf assembly 10 and circuit card assembly 12 of the present disclosure, and FIG. 9B illustrates a further possible cooling air configuration utilized with the shelf assembly 10 and circuit card assembly 12 of the present disclosure. A narrow backplane version is shown in FIG. 9A, and a wide backplane version is shown in FIG. 9B. In both versions, fans 44 draw cooling air from the front of the system through the back of the system, around the ASIC 18, client ports 22, and fabric ports 24. Adjacent to the fans 44 on either side are vertical liquid manifolds 46 that interface with quick disconnect fittings 48 on each circuit card 12. This system could be cooled without liquid with the help of a large heat-spreading vapor chamber disposed over the hot ASIC 18.

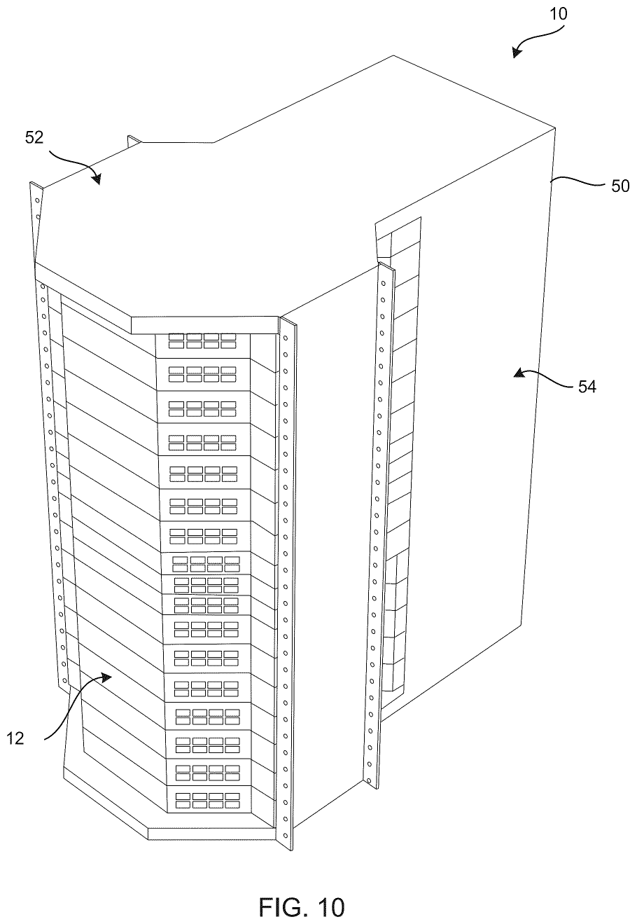

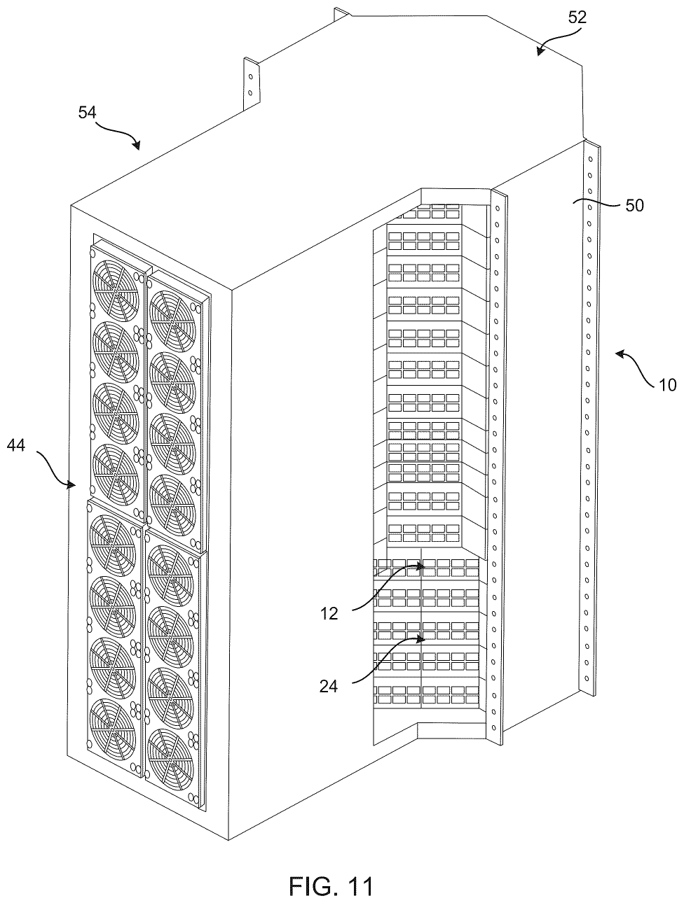

FIGS. 10 and 11 illustrate the front and back of one embodiment of the shelf assembly 10 of the present disclosure with a plurality of circuit cards assemblies (Client boxes and Fabric boxes) 12 installed in a vertical stack. As can be seen, the shelf assembly 10 includes a housing 50 and circuit card assemblies 12 that include a generally octagonal front portion 52 and a generally rectangular rear portion 54 at which the plurality of fans 44 are disposed. From the rear, it can be seen that the fabric ports 24 are arranged in a patch panel type of arrangement for fabric cable connections from Fabric boxes to Client boxes.

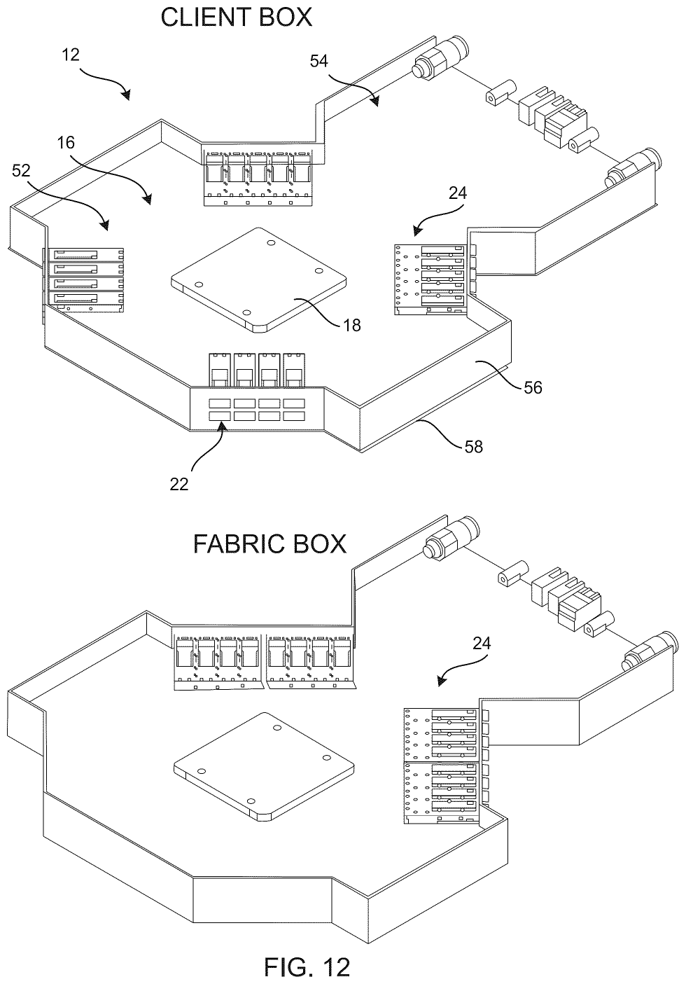

FIG. 12 illustrates one embodiment of the circuit card assembly 12 of the present disclosure. The board 16 of the circuit card assembly 12 is disposed within a case 56 that encloses the ASIC 18, client ports 22, fabric ports 24, and other components disposed on the board 16 in the generally octagonal front portion 52 and the generally rectangular or other shaped rear portion 54, providing appropriate user access to the client ports 22 and fabric ports 24 from the front and back of the circuit card assembly 12 and shelf assembly 10. The case 56 forms or includes a guide rail 58 on each side thereof that guides insertion of the circuit card assembly 12 into the shelf assembly 10 at a desired level.

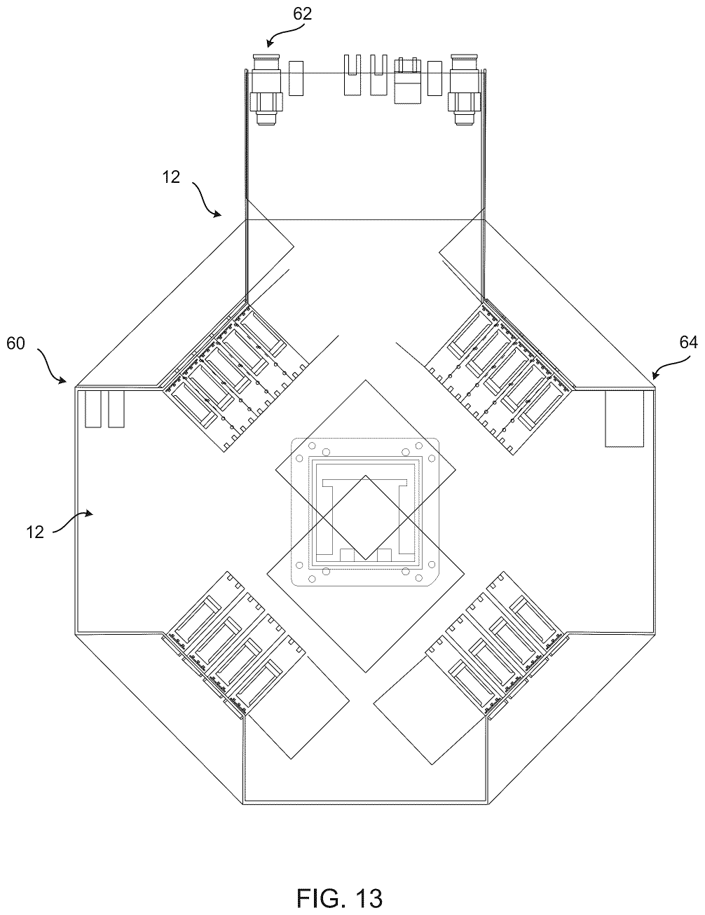

Referring to FIG. 13, it can be seen that busbars 60 are provided on and rise up the back side of the shelf assembly 10 and circuit cards 12, where the busbars 60 may also be cooled. Guide pins 62 are provided to control circuit card-shelf alignment. Control 64 is provided on a backplane proximate an access panel to allow communication with control cards. The backplane is wider in control section, but may be narrowed if air is not pushed through. The backplane may be shaped like a cross as the control cards need a lot of interconnect in the middle of the system, where the control cards reside. All connectors need the guide pins 62 close by so they do not bend pins. A full height but narrow backplane with the guide pins 62 can control the alignment of all components. In general, appropriate internal gaps must be provided for any liquid cooling lines used, the tracking of power planes, and any board level cold plates designed to distribute liquid for cooling.

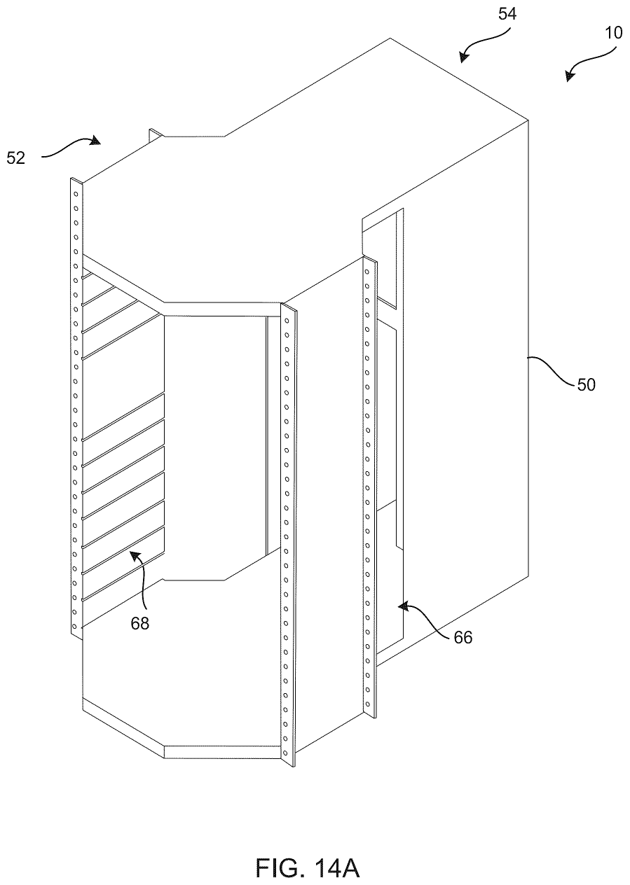

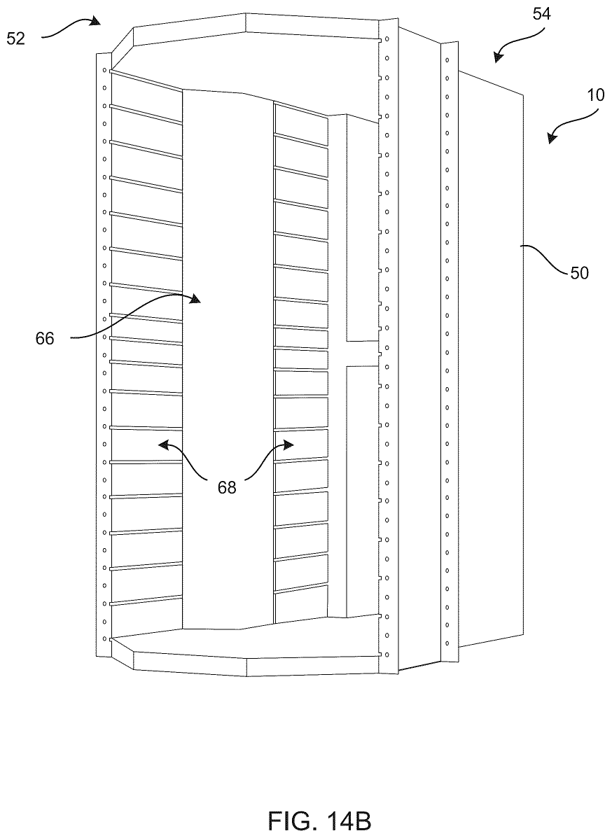

FIG. 14A illustrates an embodiment of the shelf assembly 10 of the present disclosure, and FIG. 14B illustrates another embodiment of the shelf assembly 210 of the present disclosure. The housing 50 is configured to accommodate four sides of port access around the generally octagonal portion 52, adjacent to the generally rectangular portion 54 in the rear. In one embodiment, the shelf assembly 10 has a wide front section to support the front of the circuit card assemblies 12. The width is sized to fit in a 19 inch equipment rack, for example, and the narrower rear section is designed to support the rear of the packs and guide the associated connections to a narrow backplane. There are left and right side openings 66 to allow rear access to cabling for fabric connections. Thus, the rear section is narrower to allow good access for cabling fabric ports. The generally octagonal shape of the circuit card assemblies 12 greatly increases the number of ports 22 and 24 that can be used to interface to an ASIC 18. Any number of client ports 22 may be added to the front side of each circuit card assembly, based on the associated ASIC placement. The housing 50 of the shelf assembly 10 defines internal guide slots 68 that are configured to receive the guide rails 58 of each circuit card assembly 12. In another embodiment, the rear portion of the shelf assembly is wider and also defines internal guide slots 68 that are configured to receive the guide rails 58 of each circuit card assembly 12.

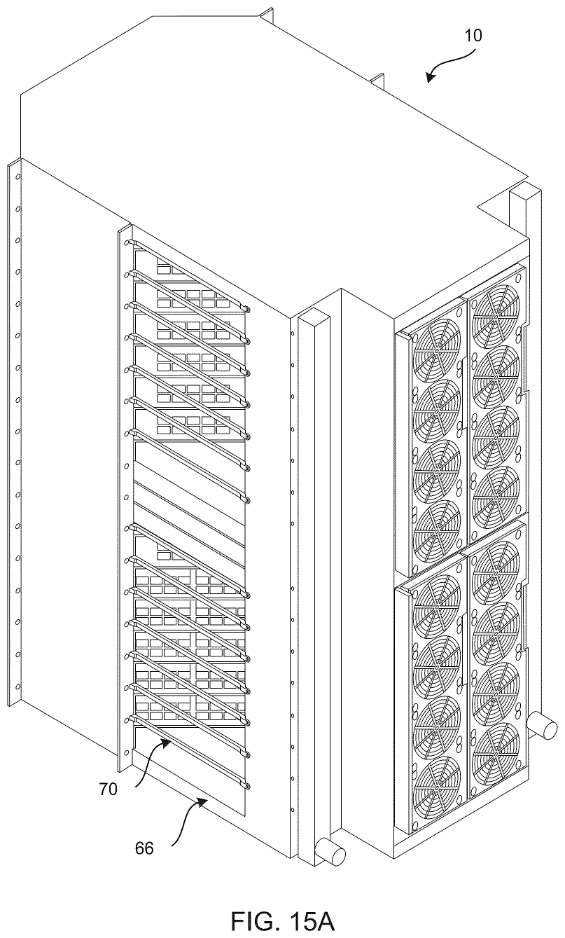

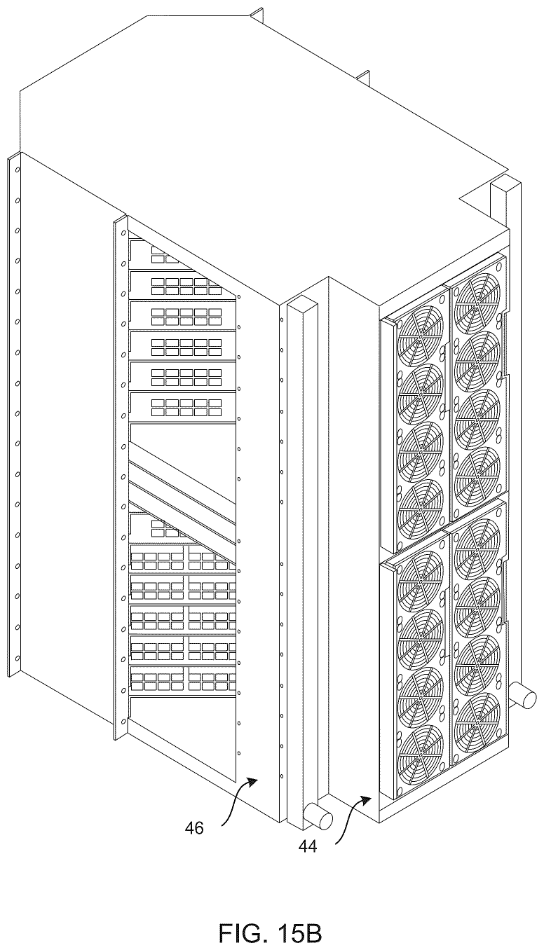

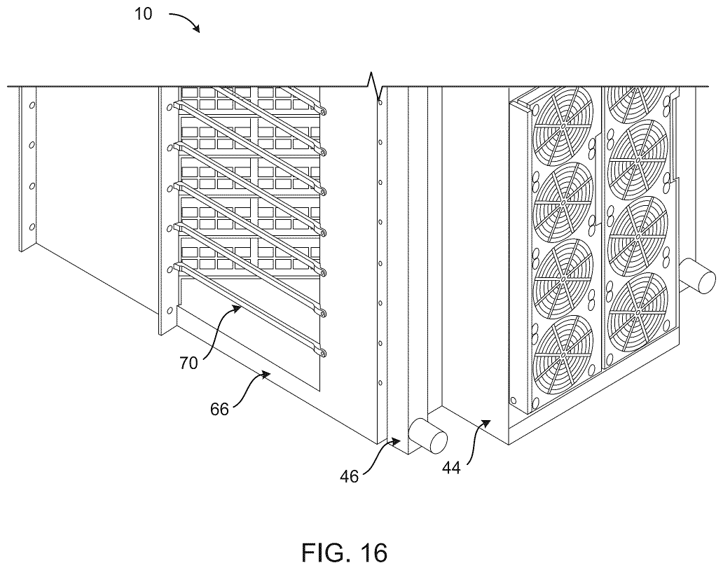

FIG. 15A illustrates another embodiment of the shelf assembly of the present disclosure, and FIG. 16B illustrates the embodiment of the shelf assembly of the present disclosure with a removable track. Referring to FIGS. 15A, 15B and 16, relative to a shelf assembly 10 that accommodates circuit card assemblies 12 with a wider rear portion, a removable guide track 70 may be disposed between corresponding guide slots 68 present at each of the front portion and the rear portion of each side of the shelf assembly, spanning the associated opening. This removable guide track 70 thus provides a continuous track for the associated guide rail 58 of the circuit card assembly 12 as it is inserted into the shelf assembly 10, from initial insertion to complete insertion. Once selected or all circuit pack assemblies 12 are installed into the shelf assembly 10, the removable guide tracks 70, which are screwed or otherwise removably affixed to the shelf assembly 10, may be removed such that they do not interfere with user access to the ports 22 and 24 accessible through the associated opening 66. Also illustrated in FIGS. 15A, 15B, and 16 are the fans 44 of the air cooling system of the shelf assembly 10 and the vertical liquid manifolds 46 of the liquid cooling system of the shelf assembly 10.

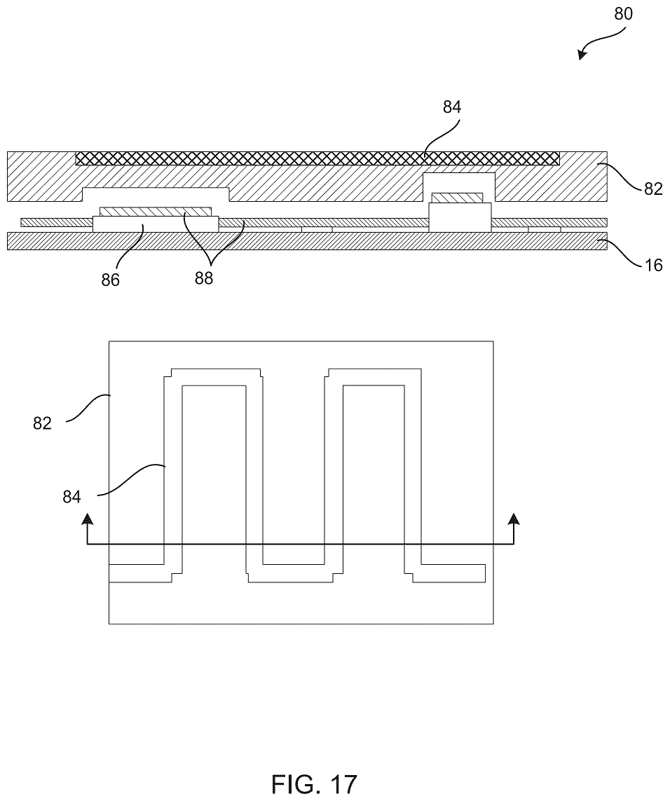

FIG. 17 illustrates one embodiment of a liquid cooling system 80 for the circuit card assemblies 12 of the present disclosure. As alluded to above, each circuit card assembly 12 may be hooked into a cooling liquid distribution system via quick disconnects 36 associated with each circuit card assembly 12. Within the circuit card 12, the liquid cooling system 80 includes a cooling plate 82 that is disposed adjacent to a component surface (primary and/or secondary) of the board 16, this cooling plate 82 including embedded conduits 84, such as copper tubing sections or the like, for circulating a cooling fluid about the component surface of the board 16, thereby drawing heat away from the components 86 disposed thereon. Thermally conductive pads or gel 88 may disposed between the cooling plate and the components 86 disposed on the board 16, which may be shorter and taller. The bottom surface of the cooling plate 82 may recessed to better accommodate and conform to the taller components 86.

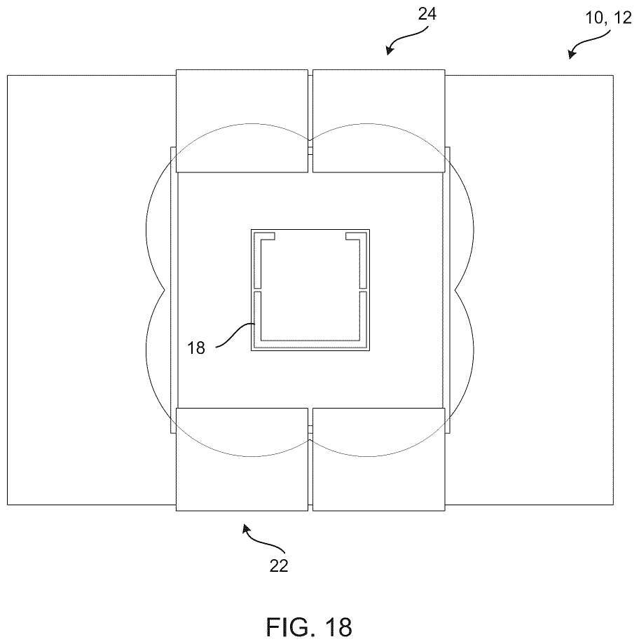

FIG. 18 illustrates a still further embodiment of the shelf assembly 10 and circuit card assembly 12 of the present disclosure. Here, the shelf assembly 10 and circuit card assembly 12 are configured in a generally rectangular shape, with the client ports 22 on a front side and the fabric ports 24 on a back side.

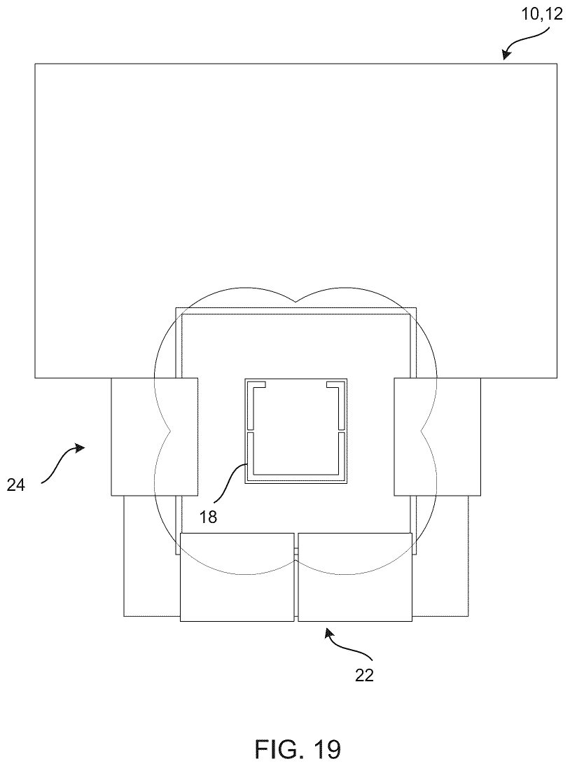

FIG. 19 illustrates a still further embodiment of the shelf assembly 10 and circuit card assembly 12 of the present disclosure. Here, the shelf assembly 10 and circuit card assembly 12 are again configured in a generally rectangular shape, with the client ports 22 on a front side and the fabric ports 24 on the left and sight sides.

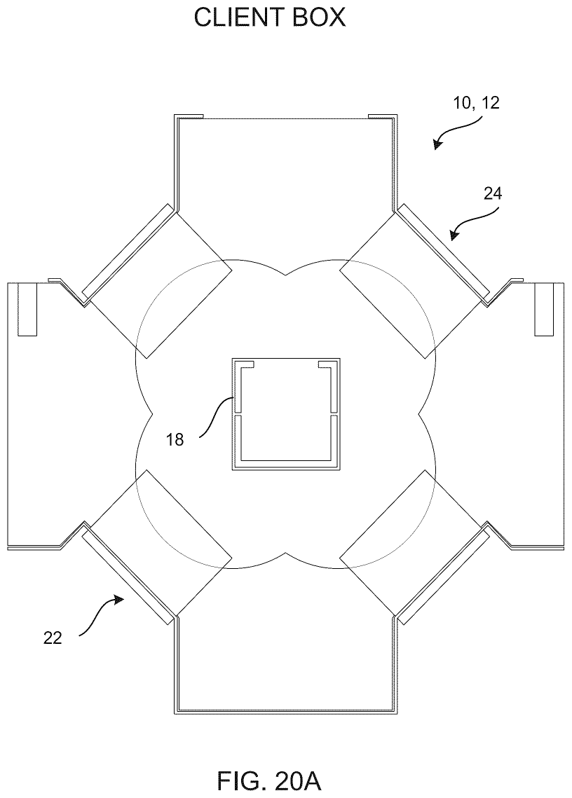

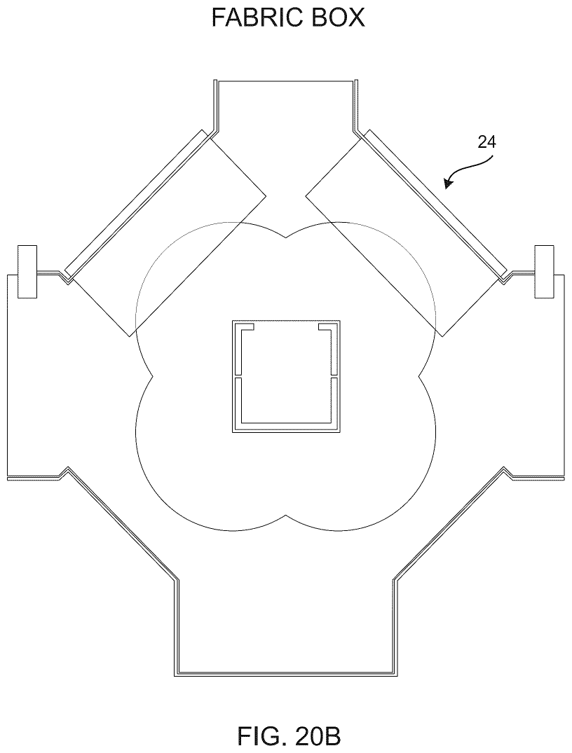

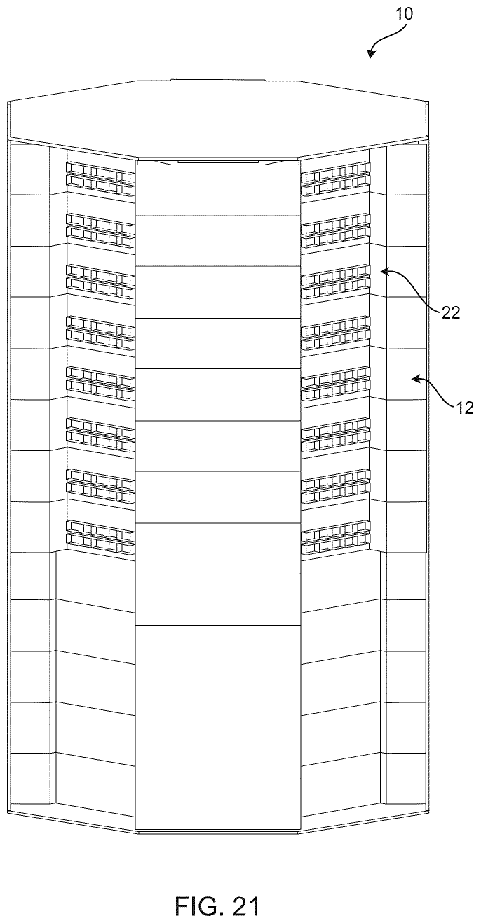

FIGS. 20A, 20B, and 21 illustrate a still further embodiment of the shelf assembly 10 and circuit card assembly 12 of the present disclosure. Particularly, FIG. 20A illustrates an embodiment of the client box, FIG. 20B illustrates an embodiment of the fabric box, and FIG. 21 illustrates an embodiment of the shelf assembly and circuit card assembly. Here, the shelf assembly 10 and circuit card assembly 12 are configured in a generally symmetrical octagonal shape, with the client ports 22 on a front side and the fabric ports 24 on a back side. Liquid cooling connections, busbars, and other connectors are all generally provided on the back side of the shelf assembly 10 and circuit card assembly 12.

Thus, the present disclosure is based on the concept that it is possible to reduce power consumption by arranging client ports closer to the designated client connections of the ASIC and fabric ports closer to the designated fabric connections of the ASIC. It is desirable to position the QSFP-DD/OSFP connectors within about 3 inches of these ASIC connections. Thus, the client ports are positioned on the front corners, and optionally along the front face, of a generally octagonal circuit card, with the fabric ports positioned on the rear corners. The side faces of the circuit card may be reserved for mounting guidance.

The ports or connections of the ASIC are arranged around the perimeter of the generally square ASIC body, with the client ports on the front side and half way back along adjacent sides of the ASIC body, for example. On the same chip, the fabric ports may be arranged around the opposite back corners. To reduce track length as much as possible, the QSFP-DD/OSFP connectors that interact with the ASIC are disposed at substantially 45-degree angles to the ASIC on all four corners. If the ASIC body represents four sides of the square, then the QSFP-DD/connectors are arranged at 45 degrees to the square, forming a generally octagonal circuit card arrangement. The ASIC may also be rotated 45 degrees such that the sides of the ASIC body are parallel to the port surfaces, with the appropriate connections being disposed in closest proximity on the ASIC.

In this generally octagonal arrangement, the client ports are arranged towards the front outer corners of the equipment frame, while the rear outer corners of the equipment frame are used for fabric switching. The side faces of the circuit card assembly are reserved for mounting guidance when the circuit card assembly is inserted into the shelf assembly. An extended rear portion of the circuit card assembly disposed between the back corner fabric ports provides area for power entry and handling, control, and liquid cooling ingress and egress, when used. In general, the shelf and circuit card assemblies of the present disclosure may utilize air cooling and/or liquid cooling, such as in a hybrid cooling system.

As contemplated herein, by way of example only, there are two types of circuit card assemblies that may be used in the shelf assembly, providing a switching fabric topology. A circuit card assembly with client ports to be switched may be referred to as a Client box, which may also include fabric ports to exchange data with a second type of fabric box circuit card assembly referred to as a Fabric box. Thus, the present disclosure contemplates multiple similar arrangements of client ports and fabric ports on circuit card assemblies that plug into a unique generally octagonal shaped shelf assembly, providing four sides of port access with minimized signal track length, reduced power consumption, and improved cooling efficiency.

Although the present disclosure is illustrated and described with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A circuit card assembly adapted to be inserted into a conformal shelf assembly, the circuit card assembly comprising:
a printed circuit board assembly disposed in a case; and
a plurality of ports coupled to the printed circuit board and accessible from a rear facing side of the case.

2. The circuit card assembly of claim 1, wherein the plurality of ports comprise a plurality of fabric ports, and further comprising a plurality of client ports coupled to the printed circuit board and accessible from a front facing side of the case.

3. The circuit card assembly of claim 2, wherein the case comprises a generally octagonal shaped portion and:
the plurality of fabric ports are accessible from a rear and side facing corner of the case; and
the plurality of client ports are accessible from a front and side facing corner of the case.

4. The circuit card assembly of claim 2, further comprising an application specific integrated circuit coupled to the printed circuit board and disposed between the plurality of fabric ports and the plurality of client ports in a central portion of the printed circuit board.

5. The circuit card assembly of claim 3, wherein the case further comprises a generally rectangular shaped portion or a generally tail shaped portion coupled to the generally octagonal shaped portion at a back portion of the case.

6. The circuit card assembly of claim 5, wherein the generally rectangular shaped portion or the generally tail shaped portion comprises one or more of:
a busbar;
a controller;
a plurality of guide pins; and
a plurality of cooling liquid quick disconnects.

7. The circuit card assembly of claim 1, further comprising a liquid cooling plate disposed within the case adjacent to a component side of the printed circuit board, and further comprising guide rails coupled to sides of the case.

8. A shelf assembly adapted to receive an inserted conformal circuit card assembly, the shelf assembly comprising:
a housing defining an opening on a rear facing side of the housing adapted to provide access to a plurality of ports of the circuit card assembly from the rear facing side of the housing.

9. The shelf assembly of claim 8, wherein the plurality of ports comprise a plurality of fabric ports, and wherein the housing further defines an opening on a front facing side of the housing adapted to provide access to a plurality of client ports of the circuit card assembly from the front facing side of the housing.

10. The shelf assembly of claim 9, wherein the housing comprises a generally octagonal shaped portion and:
the plurality of fabric ports are accessible from a rear and side facing corner of the housing; and
the plurality of client ports are accessible from a front and side facing corner of the housing.

11. The shelf assembly of claim 9, where the circuit card assembly includes an application specific integrated circuit coupled to a printed circuit board with the plurality of fabric ports and the plurality of client ports and disposed between the plurality of fabric ports and the plurality of client ports in a central portion of the printed circuit board.

12. The shelf assembly of claim 10, wherein the housing further comprises a generally rectangular shaped portion or a generally tail shaped portion coupled to the generally octagonal shaped portion at a back portion of the housing.

13. The shelf assembly of claim 12, wherein the generally rectangular shaped portion or the generally tail shaped portion comprises one or more of:
a backplane;
a plurality of guide pins; and
a plurality of cooling liquid quick disconnects.

14. The shelf assembly of claim 8, further comprising one or more of:
a vertical air plenum disposed at a back of the housing;
a vertical air plenum disposed at a side of the housing;
a vertical liquid manifold disposed at the back of the housing;
one or more fan assemblies disposed at the back of the housing;
one or more fan assemblies disposed at the side of the housing; and
one or more fan assemblies disposed at a top of the housing.

15. The shelf assembly of claim 8, wherein sides of the housing define internal guide slots adapted to receive guide rails coupled to sides of a case of the circuit card assembly.

16. The shelf assembly of claim 15, wherein each of the internal guide slots is formed within, in part, a removable guide rail coupled to a side of the housing and spanning the opening on the rear facing side of the housing adapted to provide access to the plurality of fabric ports of the circuit card assembly from the rear facing side of the housing.

17. A shelf system for use in a telecommunications or networking application, the shelf system comprising:
a shelf assembly; and
a circuit card assembly conformally inserted into the shelf assembly;
wherein the circuit card assembly comprises:
a printed circuit board assembly disposed in a case; and
a plurality of ports coupled to the printed circuit board and accessible from a rear facing side of the case; and
wherein the shelf assembly comprises:
a housing defining an opening on a rear facing side of the housing adapted to provide access to the plurality of ports of the circuit card assembly from the rear facing side of the housing.

18. The shelf system of claim 17, wherein the plurality of ports comprise a plurality of fabric ports, and wherein:
the circuit card assembly further comprises a plurality of client ports coupled to the printed circuit board and accessible from a front facing side of the case; and
the housing of the shelf assembly further defines an opening on a front facing side of the housing adapted to provide access to the plurality of client ports of the circuit card assembly from the front facing side of the housing.

19. The shelf system of claim 18, wherein the case and the housing each comprise a generally octagonal shaped portion and:
the plurality of fabric ports are accessible from a rear and side facing corner of the case and housing; and
the plurality of client ports are accessible from a front and side facing corner of the case and housing.

20. The shelf system of claim 18, wherein the circuit card assembly further comprises an application specific integrated circuit coupled to the printed circuit board and disposed between the plurality of fabric ports and the plurality of client ports in a central portion of the printed circuit board.
